(19) United States
(12) Patent Application Publication
(10) Pub. No.: US 2026/0179875 A1
(43) Pub. Date: Jun. 25, 2026

(54) CORRECTING SCAN DATA

(71) Applicant: ASML NETHERLANDS B.V., Veldhoven (NL)

(72) Inventors: Victor Emanuel CALADO, Rotterdam (NL); Andrea AMORESE, Eindhoven (NL); Jasper Frans Mathijs VAN RENS, Hegelsom (NL); Thomas Jarik HUISMAN, Eindhoven (NL)

(73) Assignee: ASML NETHERLANDS B.V., Veldhoven (NL)

(21) Appl. No.: 19/121,415

(22) PCT Filed: Oct. 13, 2023
(86) PCT No.: PCT/EP2023/078520

§ 371 Date: Apr. 15, 2025

(30) Foreign Application Priority Data
Nov. 9, 2022 (EP) 22206511.2

(51) Int. Cl. H01J 37/26; H01J 37/28

(52) U.S. Cl. CPC H01J 37/265; H01J 37/28; H01J 2237/1536

(57) ABSTRACT

A method for correcting scan data generated by scanning a sample with charged particles and detecting signal charged particles emitted from the sample, the method including selecting at least one scan profile for scanning the sample; and correcting scan data generated by the scanning of the sample, based on at least one known distortion function f(x,y) associated with the at least one selected scan profile.

### CROSS-REFERENCE TO RELATED APPLICATIONS

This application claims priority of EP application 22206511.2 which was filed on Nov. 9, 2022 and which is incorporated herein in its entirety by reference.

### TECHNICAL FIELD

The embodiments provided herein disclose a method for for correcting scan data, a charged particle-optical apparatus and a non-transitory computer readable medium.

### BACKGROUND

In manufacturing processes of integrated circuits (ICs), unfinished or finished circuit components are assessed to ensure that they are manufactured according to design and are free of defects. Assessment (e.g. metrology or inspection) systems utilizing optical microscopes or charged particle (e.g., electron) beam microscopes, such as a scanning electron microscope (SEM) can be employed. As the physical sizes of IC components continue to shrink, and their structures continue to become more complex, accuracy and throughput in assessment (e.g. metrology or defect detection and inspection) become more important. The overall image quality depends on a combination of high secondary-electron and backscattered-electron signal detection efficiencies, among others. Backscattered electrons have higher emission energy to escape from deeper layers of a sample, and therefore, their detection may be desirable for imaging of complex structures such as buried layers, nodes, high-aspect-ratio trenches or holes of 3D NAND devices. For applications such as critical dimension, periodicity and placement error metrology, it may be desirable to obtain high quality imaging and efficient collection of surface information from secondary electrons and buried layer information from backscattered electrons, simultaneously, highlighting a need for using multiple electron detectors in a SEM. Although multiple electron detectors in various structural arrangements may be used to maximize collection and detection efficiencies of secondary and backscattered electrons individually, the combined detection efficiencies remain low, and therefore, the image quality achieved may be inadequate for high accuracy and high throughput assessment of two-dimensional and three-dimensional structures.

### SUMMARY

An embodiment of the present disclosure provides a method for correcting scan data generated by scanning a sample with charged particles and detecting signal charged particles emitted from the sample, the method comprising: selecting at least one scan profile for scanning the sample based on at least one known distortion function, indicative of distortion of scan data, associated with the at least one selected scan profile; and correcting scan data generated by the scanning of the sample, based on the at least one known distortion function associated with the at least one selected scan profile.

An embodiment of the present disclosure provides a charged particle-optical apparatus scanning a sample with charged particles and detecting signal charged particles emitted from the sample, the charged particle-optical apparatus comprising: a charged particle-optical device configured to direct a charged particle beam onto the sample, according to a selected at least one scan profile selected based on at least one known distortion function that is indicative of distortion of scan data and is associated with the at least one selected scan profile; a detector configured to detect signal charged particles emitted from the sample, so as to generate scan data; and a controller configured to correct the scan data, based on the at least one known distortion function associated with the at least one selected scan profile.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

The above and other aspects of the present disclosure will become more apparent from the description of exemplary embodiments, taken in conjunction with the accompanying drawings in which:

FIG. 1 is a schematic diagram illustrating an exemplary electron beam assessment system, consistent with embodiments of the present disclosure.

FIG. 2A, FIG. 2B, and FIG. 2C are schematic diagrams illustrating exemplary electron beam tools, consistent with embodiments of the present disclosure that may be a part of the exemplary electron beam assessment system of FIG. 1.

FIG. 3 is a diagram of candidate scan profiles.

FIG. 4 is a diagram of selection of a scan profile.

FIG. 5 is a diagram of correction of scan data.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied.

One component of improving yield is monitoring the chip making process to ensure that it is producing a sufficient number of functional integrated circuits. One way to monitor the process is to assess the chip circuit structures at various stages of their formation. Assessment can be carried out using an SEM. An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur. It may be desirable to have higher throughput for defect detection and assessment processes to meet the requirements of IC manufacturers.

One of the main challenges to assure the quality of the functional integrated circuits is an accurate measurement of the relative position of the structures/features. This position can differ from the desired design due to errors in the lithography process, which result in distortion of the printed patterns and structures. Measuring this (real) distortion, or placement error (PE) is one of the main goals of metrology. This task is complicated by the fact that other sources of artefacts and distortions may affect the acquired images. These distortions can be caused by the measuring process itself, for example due to hardware problems in the SEM tool, or to sample charging (i.e. SEM-induced charging of the sample surface affecting the trajectories of the incoming primary electrons). Such charging-induced distortions typically depend on the way the SEM scans the structures. These distortions are not real, i.e. they are not present on the sample, and should be decoupled from the real distortion of the structure that one wants to measure on the sample. There are different ways that the SEM can scan the structures, for example different scanning patterns. Some scanning patterns may result in distortions that are more easily separated from the useful structural information about the structures themselves (i.e. the distortion, or placement error, that can be expected on the sample and can be caused by the fabrication process of the structure). By selecting a scanning pattern that causes a distortion more easily separated from the structural information of the structures themselves, the distortion caused by the way that the SEM scans the structures can be better corrected for in the SEM image.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

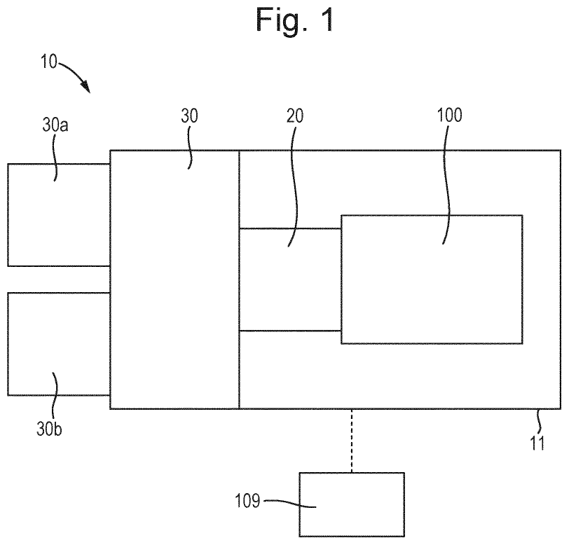

Reference is now made to FIG. 1, which illustrates an exemplary electron beam assessment system 10 that may include a detector, consistent with embodiments of the present disclosure. assessment system 10 may be used for imaging. As shown in FIG. 1, the assessment system 10 includes a main chamber 11 a load/lock chamber 20, an electron beam tool 100, and an equipment front end module (EFEM) 30. Electron beam tool 100 is located within main chamber 11. EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be assessed (wafers and samples may be collectively referred to as “samples” herein).

One or more robotic arms (not shown) in EFEM 30 may transport the wafers to load/lock chamber 20. Load/lock chamber 20 is connected to a load/lock vacuum pump system (not shown) which removes gas molecules in load/lock chamber 20 to reach a first pressure below the atmospheric pressure. After reaching the first pressure, one or more robotic arms (not shown) may transport the wafer from load/lock chamber 20 to main chamber 11. Main chamber 11 is connected to a main chamber vacuum pump system (not shown) which removes gas molecules in main chamber 11 to reach a second pressure below the first pressure. After reaching the second pressure, the wafer is subject to assessment by electron beam tool 100. Electron beam tool 100 may be a single-beam system or a multi-beam system. A controller 109 is electronically connected to electron beam tool 100, and may be electronically connected to other components as well. Controller 109 may be a computer configured to execute various controls of the assessment system 10. While controller 109 is shown in FIG. 1 as being outside of the structure that includes main chamber 11, load/lock chamber 20, and EFEM 30, it is appreciated that controller 109 can be part of the structure.

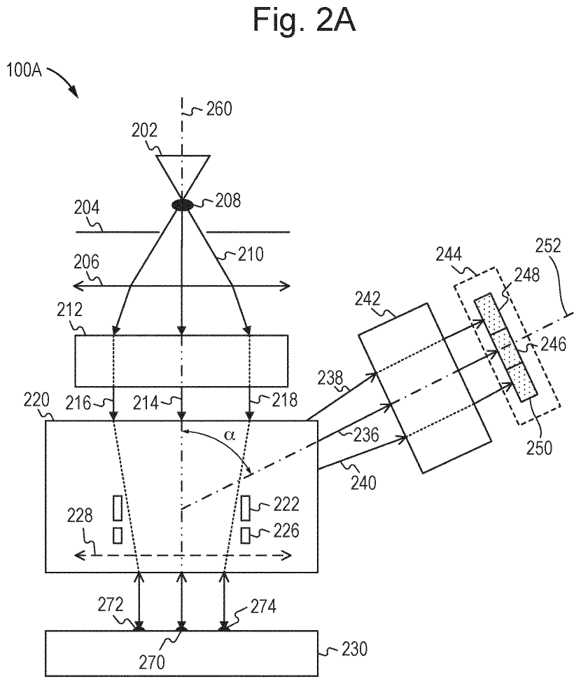

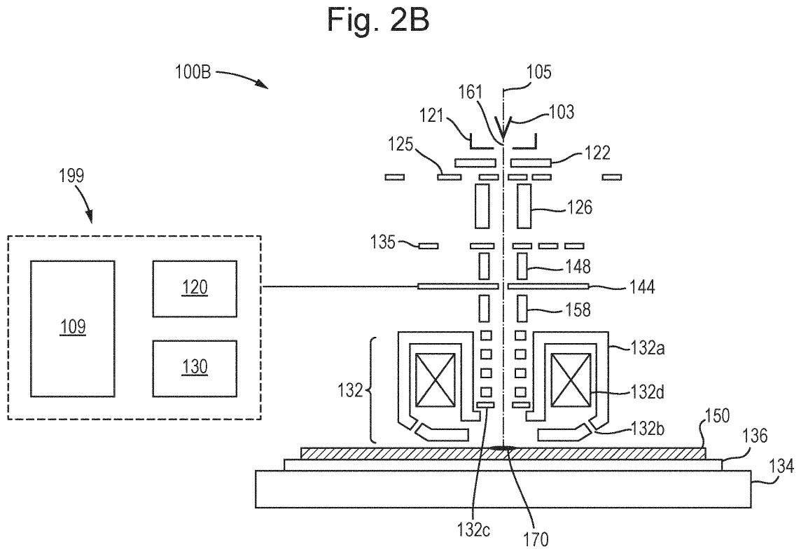

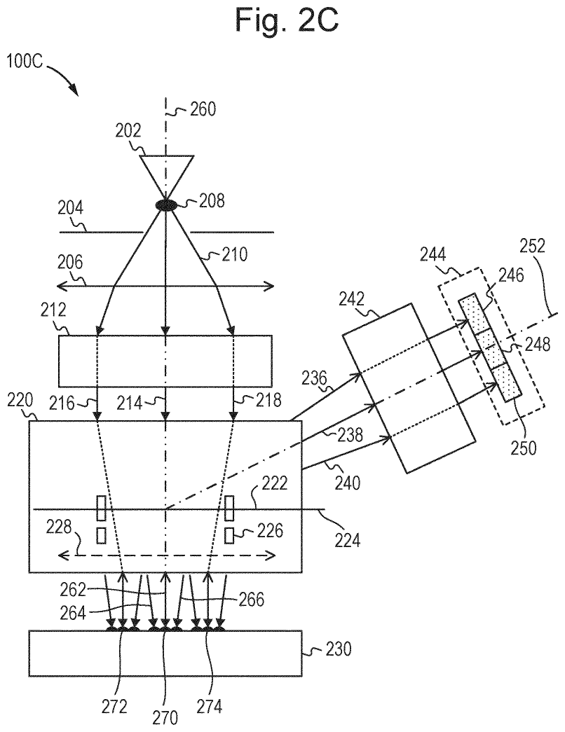

FIG. 2A illustrates a charged particle beam apparatus in which an assessment system may comprise a multi-beam assessment tool that uses multiple primary electron beamlets to simultaneously scan multiple locations on a sample.

As shown in FIG. 2A, an electron beam tool 100A (also referred to herein as an electron beam apparatus 100A or an electron-optical device) may comprise an electron source 202, a gun aperture 204, a condenser lens 206, a primary electron beam 210 emitted from electron source 202, a source conversion unit 212, a plurality of beamlets 214, 216, and 218 of primary electron beam 210, a primary projection optical system 220, a wafer stage (not shown in FIG. 2A), multiple secondary electron beams 236, 238, and 240, a secondary optical system 242, and an electron detection device 244. Electron source 202 may generate primary particles, such as electrons of primary electron beam 210. A controller, image processing system, and the like may be coupled to electron detection device 244. Primary projection optical system 220 may comprise a beam separator 222, deflection scanning unit 226, and objective lens 228. Electron detection device 244 may comprise detection sub-regions 246, 248, and 250.

Electron source 202, gun aperture 204, condenser lens 206, source conversion unit 212, beam separator 222, deflection scanning unit 226, and objective lens 228 may be aligned with a primary optical axis 260 of electron beam apparatus 100A. Secondary optical system 242 and electron detection device 244 may be aligned with a secondary optical axis 252 of electron beam apparatus 100A.

Electron source 202 may comprise a cathode, an extractor or an anode, wherein primary electrons can be emitted from the cathode and extracted or accelerated to form a primary electron beam 210 with a crossover (virtual or real) 208. Primary electron beam 210 can be visualized as being emitted from crossover 208. Gun aperture 204 may block off peripheral electrons of primary electron beam 210 to reduce size of probe spots 270, 272, and 274.

Source conversion unit 212 may comprise an array of image-forming elements (not shown in FIG. 2A) and an array of beam-limit apertures (not shown in FIG. 2A). An example of source conversion unit 212 may be found in U.S. Pat. No. 9,691,586; U.S. Publication No. 2017/0025243; and International Application No. PCT/EP2017/084429, all of which are incorporated by reference in their entireties. The array of image-forming elements may comprise an array of micro-deflectors or micro-lenses. The array of image-forming elements may form a plurality of parallel images (virtual or real) of crossover 208 with a plurality of beamlets 214, 216, and 218 of primary electron beam 210. The array of beam-limit apertures may limit the plurality of beamlets 214, 216, and 218.

Condenser lens 206 may focus primary electron beam 210. The electric currents of beamlets 214, 216, and 218 downstream of source conversion unit 212 may be varied by adjusting the focusing power of condenser lens 206 or by changing the radial sizes of the corresponding beam-limit apertures within the array of beam-limit apertures. Condenser lens 206 may be a moveable condenser lens that may be configured so that the position of its first principle plane is movable. The movable condenser lens may be configured to be magnetic, which may result in off-axis beamlets 216 and 218 landing on the beamlet-limit apertures with rotation angles. The rotation angles change with the focusing power and the position of the first principal plane of the movable condenser lens. In some embodiments, the moveable condenser lens may be a moveable anti-rotation condenser lens, which involves an anti-rotation lens with a movable first principal plane. A moveable condenser lens is further described in U.S. Publication No. 2017/0025241, which is incorporated by reference in its entirety.

Objective lens 228 may focus beamlets 214, 216, and 218 onto a wafer 230 (i.e. a sample) for assessment and may form a plurality of probe spots 270, 272, and 274 on the surface of wafer 230.

Beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. Beam separator 222 may separate secondary electron beams 236, 238, and 240 from beamlets 214, 216, and 218 and direct secondary electron beams 236, 238, and 240 towards secondary optical system 242.

Deflection scanning unit 226 may deflect beamlets 214, 216, and 218 to scan probe spots 270, 272, and 274 over a surface area of wafer 230. In response to incidence of beamlets 214, 216, and 218 at probe spots 270, 272, and 274, secondary electron beams 236, 238, and 240 may be emitted from wafer 230. Secondary electron beams 236, 238, and 240 may comprise electrons with a distribution of energies including secondary electrons and backscattered electrons. Secondary optical system 242 may focus secondary electron beams 236, 238, and 240 onto detection sub-regions 246, 248, and 250 of electron detection device 244. Detection sub-regions 246, 248, and 250 may be configured to detect corresponding secondary electron beams 236, 238, and 240 and generate corresponding signals used to reconstruct an image of surface area of wafer 230.

Although FIG. 2A shows an example of electron beam tool 100 as a multi-beam tool that uses a plurality of beamlets, embodiments of the present disclosure are not so limited. For example, electron beam tool 100 may also be a single-beam tool that uses only one primary electron beam to scan one location on a wafer at a time.

As shown in FIG. 2B, an electron beam tool 100B (also referred to herein as electron beam apparatus 100B) may be a single-beam assessment tool that is used in the assessment system 10. Electron beam apparatus 100B includes an electron-optical device configured to project electrons towards a sample location (i.e. where the wafer is) and a wafer holder 136 supported by motorized stage 134 to hold a wafer 150 (i.e. a sample) to be assessed. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In an imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered primary particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of electron beam tool 100B through a medium such as an electrical conductor, optical fiber cable, portable storage media, IR, Bluetooth, Internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 158. In some embodiments, the quadrupole lenses are used for controlling the electron beam. For example, first quadrupole lens 148 can be controlled to adjust the beam current and second quadrupole lens 158 can be controlled to adjust the beam spot size and beam shape.

FIG. 2B illustrates a charged particle beam apparatus in which an assessment system may use a single primary beam that may be configured to generate secondary electrons by interacting with wafer 150. Detector 144 may be placed along optical axis 105, as in the embodiment shown in FIG. 2B. The primary electron beam may be configured to travel along optical axis 105. Accordingly, detector 144 may include a hole at its center so that the primary electron beam may pass through to reach wafer 150. However, some embodiments may use a detector placed off-axis relative to the optical axis along which the primary electron beam travels. For example, as in the embodiment shown in FIG. 2A, beam separator 222 may be provided to direct secondary electron beams toward a detector placed off-axis. Beam separator 222 may be configured to divert secondary electron beams by an angle α.

Another example of a charged particle beam apparatus will now be discussed with reference to FIG. 2C. Electron beam tool 100C (also referred to herein as an electron beam apparatus 100C or an electron-optical device) may be an example of electron beam tool 100 and may be similar to electron beam tool 100A shown in FIG. 2A.

As shown in FIG. 2C, beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. For a dispersion plane 224 of beam separator 222, FIG. 2C shows dispersion of beamlet 214 with nominal energy V0 and an energy spread ΔV into beamlet portions 262 corresponding to energy V0, beamlet portion 264 corresponding to energy V0+ΔV/2, and beamlet portion 266 corresponding to energy V0-ΔV/2. The total force exerted by beam separator 222 on an electron of secondary electron beams 236, 238, and 240 can be non-zero. Beam separator 222 may separate secondary electron beams 236, 238, and 240 from beamlets 214, 216, and 218 and direct secondary electron beams 236, 238, and 240 towards secondary optical system 242.

A semiconductor electron detector (sometimes called a “PIN detector”) may be used in apparatus 100 in the assessment system 10. The assessment system 10 may be a high-speed wafer imaging SEM including an image processor. An electron beam generated by the assessment system 10 may irradiate the surface of a sample or may penetrate the sample. The assessment system 10 may be used to image a sample surface or structures under the surface, such as for analyzing layer alignment. In some embodiments, the assessment system 10 may detect and report process defects relating to manufacturing semiconductor wafers by, for example, comparing SEM images against device layout patterns, or SEM images of identical patterns at other locations on the wafer under assessment. A PIN detector may include a silicon PIN diode that may operate with negative bias. A PIN detector may be configured so that incoming electrons generate a relatively large and distinct detection signal. In some embodiments, a PIN detector may be configured so that an incoming electron may generate a number of electron-hole pairs while a photon may generate just one electron-hole pair. A PIN detector used for electron counting may have numerous differences as compared to a photodiode used for photon detection, as shall be discussed as follows.

In an embodiment the detector (e.g. the electron detection device 244 shown in FIG. 2A or FIG. 2C or the detector 144 shown in FIG. 2B) comprises a plurality of detector elements (e.g. detection sub-regions 246, 248, and 250). The detector elements may be connected to one or more circuit layers. A circuit layer of the detector may comprise circuitry having amplification and/or digitation functions, e.g. it may comprise a amplification circuit. A circuit layer may comprise one or more trans impedance amplifiers (TIAs) and one or more ADCs. A detector element and an associated feedback resistor may be connected to the TIA and ADC. One or more digital signal lines may be connected from the ADC for transferring digital signals, e.g. to the image acquirer 120 shown in FIG. 2B.

In some embodiments, a detector may communicate with a controller that controls a charged particle beam system. The controller may instruct components of the charged particle beam system to perform various functions, such as controlling a charged particle source to generate a charged particle beam and controlling a deflector to scan the charged particle beam. The controller may also perform various other functions such as adjusting a sampling rate of a detector, resetting a sensing element, or performing image processing. In an embodiment the controller is configured to control settings of the ADCs. The controller may comprise a storage that is a storage medium such as a hard disk, random access memory (RAM), other types of computer readable memory, and the like. The storage may be used for saving scanned raw image data as original images, and post-processed images. A non-transitory computer readable medium may be provided that stores instructions for a processor of controller 109 to carry out charged particle beam detection, sampling period determination, image processing, or other functions and methods consistent with the present disclosure. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a ROM, a PROM, and EPROM, a FLASH-EPROM or any other flash memory, NVRAM, a cache, a register, any other memory chip or cartridge, and networked versions of the same.

Block diagrams in the figures may illustrate the architecture, functionality, and operation of possible implementations of systems, methods, and computer hardware/software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

An electron beam apparatus 100, such as is shown in FIG. 2A, FIG. 2B or FIG. 2C may scan a sample with one or more electron beams. The electron beam apparatus 100 is configured to detect signal electrons emitted from the sample so as to generate scan data. The scan data may be image data. An image may be generated from the scan data. The scan data may be data of currents of signal electrons emitted from different locations of the sample. The electron beam apparatus 100 may be embodied as an SEM. The scan data may be SEM image data.

In an embodiment there is a method for correcting scan data. The scan data is generated by scanning a sample with charged particles (e.g. electrons) and detecting signal charged particles (e.g. electrons) emitted from the sample. It may be desirable to correct for distortion in the scan data. An image (e.g. an SEM image) that can be generated from the scan data may comprise distortion. By correcting the scan data, undesirable distortion may be reduced or eliminated.

In an embodiment the method comprises selecting at least one scan profile 51 for scanning the sample. A scan profile determines the way in which the electron beam apparatus 100 scans the sample. For example, in an embodiment the scan profile determines a scan route 52 that an electron beam follows over the sample. A scan route 52 may be a meandering path. Additionally or alternatively, a scan profile may determine one or more other parameters for the scan of the sample. For example, the scan profile may determine the current of electrons directed towards the sample, the focus of the electron beams on the sample and/or the landing energy of the electrons at the surface of the sample.

In an embodiment the controller 109 is configured to control scanning of the sample in accordance with the selected scan profile 51. For example, the controller 109 may control voltages applied to electron-optical elements (e.g. electron-optical lenses and/or deflectors) of the electron beam apparatus 100 according to the selected scan profile 51.

In an embodiment the method comprises correcting scan data based on at least one known distortion function associated with the at least one selected scan profile 51. There may be a plurality of different scan profiles according to which the electron beam apparatus 100 is capable of scanning the sample. Each scan profile may be associated with a respective distortion function. The distortion function (which may also be referred to as a distortion fingerprint) associated with a scan profile is indicative of the distortion of the scan data caused by the scan profile. When the distortion function associated with the selected scan profile 51 is known, the undesirable distortion caused by the way the sample was scanned may be compensated for.

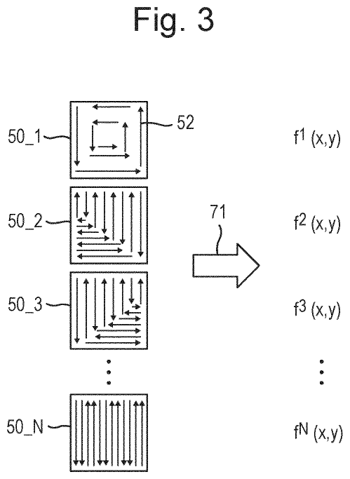

FIG. 3 schematically shows a plurality of scan profiles 50 and their associated distortion functions. Different beam scanning settings could be considered, as an example but not limited to those shown. Each beam scan setting may generate a specific charging (i.e. distortion) fingerprint. By correcting the scan data based on the known distortion function associated with the selected scan profile 51, the distortion of the scan data may be reduced. An embodiment of the disclosure is expected to reduce undesirable distortion of the scan data.

The selected scan profile 51 may be selected so as to take into account the features of the sample and the expected effects on the scan data caused by the structures of the sample itself. The expected effects caused by the structures of the sample itself may be desirable structural information. It would be undesirable to remove from the scan data information about the structures of the sample. There is a risk that when compensating for undesirable distortion, some useful structural information is also removed from the scan data.

In an embodiment, the scan profile that is selected may be selected so as to increase the extent to which the distortion induced by the scan profile can be separated from the structural information in the scan data caused by the structures of the substrate. By correcting based on a known distortion function associated with the selected scan profile, the distortion that is specific to the selected scan profile can be corrected for.

In an embodiment the scan data generated by the scanning of the sample comprises distortion and structural information. The distortion is associated with (e.g. caused by) the at least one selected scan profile 51. The distortion is undesirable. Each scan profile 50 may be associated with a distortion, i.e. a distortion of the scan data generated from the scan. For example, the distortion of the scan data may depend on the scan route 52 and/or one or more other parameters of the scan. For example, during the scan of the sample, the electron beam may charge one or more parts of the surface of the sample. The charging may depend on the extent to which structures of the sample provide a channel for charges to transfer into or through the sample. The charging of parts of the surface of the sample can affect the currents of electrons emitted from the sample. The charging induced by the electron beam apparatus 100 can cause undesirable distortion of the scan data. This distortion may be dependent on the scan profile.

In addition to the distortion, the scan data may further comprise structural information. The structural information is associated with the sample. The sample may comprise a plurality of structures, for example transistors and/or DRAM structures. The types and arrangement of the structures of the sample affect the currents of electrons emitted from the surface of the sample. It may be desirable to detect the structural information of the scan data. The structural information may provide useful information about the structures of the sample.

In an embodiment the correcting of the scan data is for compensating for the distortion associated with the at least one selected scan profile 51. The distortion caused by the particular scan profile used during the scan may be reduced or eliminated. Meanwhile, the structural information indicative of the structures of the sample may be desirably retained in the scan data.

In an embodiment the selected scan profile 51 is selected based on how separable the distortions associated with candidate scan profiles 50 are from predicted structural information predicting the structural information of the scan data. A specific scan profile, or set of scan profiles, may be selected (and used for the scan). The selected scan profile (or scan profiles) may be selected so as to take into account the features of the sample and the expected structural information. In particular, the scan profile may be selected so that it is possible to optimally separate the distortion (which is undesirable) from the structural information (which may be desirable). The structural information may include a wafer fingerprint of distortions caused by the structural features of the sample. For example, the structural information may comprise pitch-walk and, stress. “Pitch walk” is a piecewise increase or decrease in the distance between neighbouring structures. This effect can be caused by errors in the production and lithography process. Here the pitch of a repetitive pattern varies over the wafer. “Stress” on the wafer or on the stack can cause displacements of the structures. This happens typically during processing steps after the lithography step, such a deposition, etch and polishing. These are examples of inaccuracies (sometimes referred to as distortions) of the structure itself. These inaccuracies are undesirable in the structures but it is desirable to measure these inaccuracies. Such effects of the structures of the sample may be due to errors in the production process. Of course, metrology distortions, caused by the SEM measurement itself, will also be present in the acquired images. Metrology distortions are artefacts (not real) and should desirably be reduced. These artefacts can arise from sample charging, but also from the SEM tool hardware.

An embodiment of the disclosure is expected to improve correction of scan data. By selecting a specific scan profile based on the distortion and the predicted structural information, the distortion can be compensated for to a greater extent without unduly removing real content of the structural information.

An alternative way of correcting scan data is to use a simple model such as a simple polynomial model to compensate for the distortion. However, use of such a simple model has a risk of overcorrecting the scan data and thereby removing real content (i.e. desirable information about the structures of the sample). An embodiment of the disclosure provides an improved method for correcting scan data that reduces the risk of undesirable over correction (i.e. the removal of useful structural information).

An embodiment of the disclosure is expected to improve correction of distortion which may be induced by the electron beam apparatus 100. In particular, on a scale of tens of nanometres, use of a simple polynomial model may not suitably correct for distortion which may be induced by the SEM. By using a specific scan profile, or set of scan profiles, which take into account the sample features and expected structural information, the scan distortion may be better corrected, particularly on small scales.

FIG. 3 shows a calibration step, in which the distortion fingerprint caused by each scan strategy is evaluated. As shown in FIG. 3, in an embodiment a plurality of candidate scan profiles 50 are identified. As indicated in FIG. 3, each candidate scan profile 50 may be associated with different scan parameters, for example different scan routes 52 over the surface of the sample. FIG. 3 shows N different scan profiles 50_1, 502, 50_3 to 50_N. FIG. 3 shows N candidate scan profiles 50. Each candidate scan profile 50 may be associated with a known distortion function. The distortion functions are shown on the right hand side of FIG. 3. The distortion functions represent the distortion of the scan data caused by the particular scan profile 50. The distortion functions may indicate distortion of the scan data for different location of the surface of the sample, indicated by the x and y variables. The superscript of each distortion function corresponds to which scan profile 50 it is associated with. For example, the distortion function with the superscript “1” is associated with the scan profile 50_1.

In an embodiment the method comprises generating a database 40 of candidate scan profiles 50 associated with distortion functions. Each distortion function indicates expected distortion effects caused by its associated candidate profile 50. Such a database 40 may be generated during a calibration phase of the method. Alternatively, the database 40 may have previously been generated. The method may be performed making use of such a database 40 that has previously been generated.

In an embodiment the database 40 is generated by using physical models to predict the expected distortion effects. Parameters of the scan may be input into a mathematical model so as to predict the distortion of scan data caused by the scan profile 50. The generation of the distortion function is represented in FIG. 3 by the arrow 71.

Additionally or alternatively, the database 40 may be generated by using empirical training to predict the expected distortion effects. For example, the scan profile 50 may be used to scan one or more samples. The distortion caused by the scan profile may be measured and used to help determine the distortion function associated with the scan profile 50.

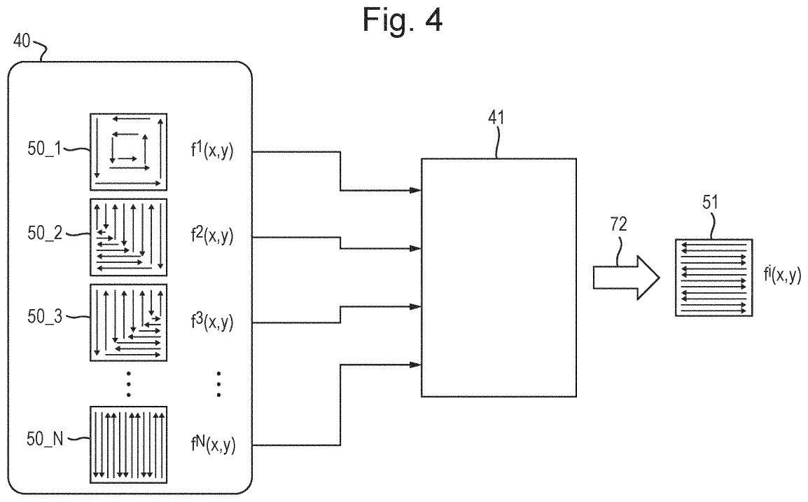

FIG. 4 schematically shows a set up for selecting a scan profile. FIG. 4 is a conceptual flow diagram of choosing the best scan strategy (or combination of scan strategies) for the specific application, i.e. the scan strategy that will give an image distortion well separated from the (non-SEM related) distortion that one wants to measure on the sample 208. In order to determine the best scan profile, one can use the multiple scan profile database 40 in the setup phase and then using a self-referencing algorithm 41 decide which scan profile 51 or profiles can be best post corrected for. FIG. 4 shows a database 40 of candidate scan profiles 50 associated with distortion functions. The selection of one of the candidate scan profiles 50 as the selected scan profile 51 is represented by the arrow 72. Although FIG. 4 shows one selected scan profile 51, in an alternative embodiment a plurality of scan profiles are selected. In an embodiment the selected scan profile 51 is the scan profile that can be best post-corrected for (i.e. corrected/compensated for after the scan data has been generated by performing the scan).

For example, in an embodiment the at least one selected scan profile 51 is selected based on how separable the distortion associated with candidate scan profiles 50 are from predicted structural information. The predicted structural information is for predicting the structural information of the scan data.

For example, in an embodiment the at least one selected scan profile 51 is selected based on how orthogonal the distortion is associated with candidate scan profiles 50 are relative to the predicted structural information. For example, a pair of two nearby vias that are mutually aligned along the x-direction of an arbitrary coordinate system, is expected to suffer from pattern placement errors in that x-direction. In that case it is better to scan SEM along the orthogonal y-direction. Then metrology artefacts will be more dominant in the y-direction and they can be separated from the pattern placement errors more easily. The predicted structural information may be predicted based on the known design of the structures intended to be formed on the sample and optionally on the lithography steps involved in fabrication.

For a given design of structures on the sample, the relationship between the predicted structural information and the distortions for different scan profiles 50 may be assessed. When the distortions are more orthogonal to each other, then they may be separated more easily. When the distortions are more orthogonal to each other, the distortion may be compensated for while affecting the structural information less.

As mentioned above, in an embodiment a plurality of scan profiles are selected for scanning the sample. In an embodiment the plurality of selected scan profiles are selected based on how orthogonal the distortions associated with candidate scan profiles are relative to each other. For example, a set of scan profiles in which the distortions are expected to be more orthogonal with respect to each other may be selected. When a set of scan profiles are used, the data from the scans may be combined. For example, independent acquisitions may be made with the selected scan profiles. The scan data may be corrected with their associated distortion functions. The two sets of scan data may be scaled by respective scaling factors. The two sets of corrected scan data may be imposed to be the same, for example by adjusting the scaling factors. This may reduce overcorrection.

In an embodiment the distortion functions associated with candidate scan profiles 50 are based on the intended design of structures of the sample. In an embodiment a candidate scan profile 50 may be associated with a plurality of distortion functions corresponding to respective designs of structures for the sample. A set of scan profiles may be selected in which the distortions are expected to be more orthogonal with respect to each other for a specific pattern (i.e. a specific design of structures of the sample). When the distortions are more orthogonal to each other, then their effects may be more easily separated from each other and compensated for independently of each other.

As shown in FIG. 4, in an embodiment the method comprises uses a self-referencing algorithm 41 to select one or more of the candidate scan profiles 50 as the selected scan profile 51. The self-referencing algorithm 41 may take into account the criteria mentioned above, for example the extent to which the distortion effects can be separated from each other and/or the extent to which the expected distortions are orthogonal to each other. The self-referencing algorithm 41 may be configured to select the scan profile that can be best post corrected for.

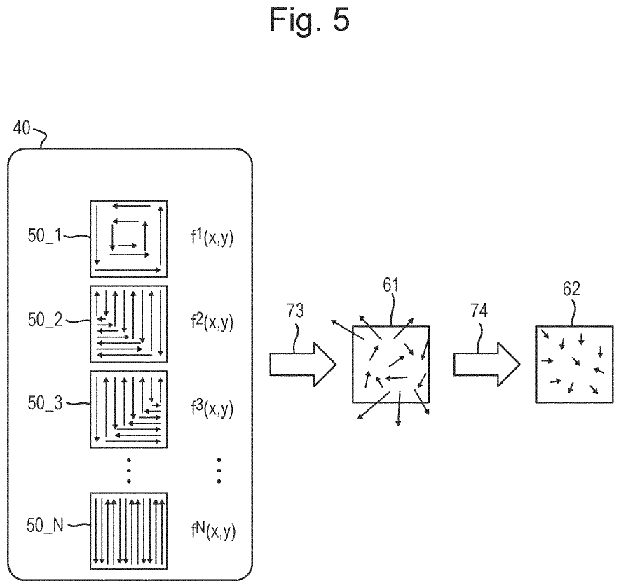

FIG. 5 schematically shows distortion correction flow using a scan profile database 40. FIG. 5 shows an example of the distortion correction flow using the scan profile database 40. FIG. 5 shows the database 40 of candidate scan profiles 50. At least one of the candidate scan profiles 50 is selected. The electron beam apparatus 100 is configured to scan the sample according to the selected scan profile 51. The scanning of the sample is represented by the arrow 73 in FIG. 5. The scanning of the sample generates scan data. The scan data comprises a complex distortion fingerprint 61. The complex distortion fingerprint 61 may be a high order distortion fingerprint.

The complex distortion fingerprint 61 may comprise distortion associated with the selected scan profile 51 and structural information providing information about the structures on the sample. In an embodiment the known distortion function associated with the at least one selected scan profile 51 is used to correct the scan data. This correction is represented by the arrow 74 in FIG. 5. The corrected scan data comprises the sample distortion 62. The suitable scan profile 51 is used for the measurement in a production mode. The distortion fingerprint 61 caused is then post corrected using the earlier knowledge of the physical modeled fingerprint from the scan profile database 40.

Of course, the correction of the distortion may not be perfect. Additionally, the structural information may be to an extent undesirably removed by the correction. Nevertheless, it is expected that the corrected scan data better represents the structural information caused by the actual structures of the sample.

In an embodiment a non-transitory computer readable medium stores instructions for a processor of a controller (e.g. the controller 109) to carry out a method as described above.

Exemplary embodiments of the present disclosure are set out in the following numbered clauses:
1. A method for correcting scan data generated by scanning a sample with charged particles and detecting signal charged particles emitted from the sample, the method comprising:
   selecting at least one scan profile for scanning the sample based on at least one known distortion function, indicative of distortion of scan data, associated with the at least one selected scan profile; and
   correcting scan data generated by the scanning of the sample, based on the at least one known distortion function associated with the at least one selected scan profile.
2. The method of clause 1, wherein the scan data generated by the scanning of the sample comprises distortion associated with the at least one selected scan profile and structural information associated with the sample, wherein the correcting is for compensating for the distortion associated with the at least one selected scan profile.
3. The method of clause 2, wherein the at least one selected scan profile is selected based on how separable the distortions associated with candidate scan profiles are from predicted structural information of the scan data.
4. The method of clause 2 or 3, wherein the at least one selected scan profile is selected based on how orthogonal the distortions associated with candidate scan profiles are relative to predicted structural information of the scan data.
5. The method of any preceding clause, wherein a plurality of selected scan profiles are selected based on how orthogonal the distortions associated with candidate scan profiles are relative to each other.
6. The method of clause 5, wherein the plurality of selected scan profiles are selected based on how orthogonal the distortions associated with candidate scan profiles are relative to each other for the sample.
7. The method of any preceding clause, comprising:
   generating a database of candidate scan profiles associated with distortion functions indicative of expected distortions caused by the respective candidate scan profiles.
8. The method of clause 7, wherein the database is generated by using physical models to predict the expected distortions.
9. The method of clause 7 or 8, wherein the database is generated by using empirical training to predict the expected distortions.
10. The method of any preceding clause, comprising:
   scanning the sample using the at least one selected scan profile.
11. The method of any preceding clause, wherein the scan profile determines a scan route that a charged particle beam follows over the sample.
12. A charged particle-optical apparatus scanning a sample with charged particles and detecting signal charged particles emitted from the sample, the charged particle-optical apparatus comprising:
   a charged particle-optical device configured to direct a charged particle beam onto the sample, according to a selected at least one scan profile selected based on at least one known distortion function that is indicative of distortion of scan data and is associated with the at least one selected scan profile;
   a detector configured to detect signal charged particles emitted from the sample, so as to generate scan data; and
   a controller configured to correct the scan data, based on the at least one known distortion function associated with the at least one selected scan profile.
13. The charged particle-optical apparatus of clause 12, wherein the scan data generated by the scanning of the sample comprises distortion associated with the at least one selected scan profile and structural information associated with the sample, wherein the correcting is for compensating for the distortion associated with the at least one selected scan profile.
14. The charged particle-optical apparatus of clause 13, wherein the controller is configured to select the at least one selected scan profile based on how separable the distortions associated with candidate scan profiles are from predicted structural information of the scan data.
15. The charged particle-optical apparatus of clause 13 or 14, wherein the controller is configured to select the at least one selected scan profile based on how orthogonal the distortions associated with candidate scan profiles are relative to predicted structural information of the scan data.
16. The charged particle-optical apparatus of any of clauses 12-15, wherein the controller is configured to select a plurality of selected scan profiles based on how orthogonal the distortions associated with candidate scan profiles are relative to each other.
17. The charged particle-optical apparatus of clause 16, wherein the controller is configured to select the plurality of selected scan profiles based on how orthogonal the distortions associated with candidate scan profiles are relative to each other for the sample.
18. The charged particle-optical apparatus of any of clauses 12-17, wherein the controller is configured to generate a database of candidate scan profiles associated with distortion functions indicating expected distortions caused by the respective candidate scan profiles.
19. The charged particle-optical apparatus of clause 18, wherein the controller is configured to generate the database by using physical models to predict the expected distortions.
20. The charged particle-optical apparatus of clause 18 or 19, wherein the controller is configured to generate the database by using empirical training to predict the expected distortions.
21. The charged particle-optical apparatus of any of clauses 12-20, wherein the controller is configured to scan the sample by directing the charged particle beam along a scan route over the sample defined by the at least one selected scan profile.
22. A non-transitory computer readable medium that stores instructions for a processor of a controller to carry out a method for correcting scan data generated by scanning a sample with charged particles and detecting signal charged particles emitted from the sample, the method comprising:
   selecting at least one scan profile for scanning the sample based on at least one known distortion function, indicative of distortion of scan data, associated with the at least one selected scan profile; and
   correcting scan data generated by the scanning of the sample, based on the at least one known distortion function associated with the at least one selected scan profile.
23. A method of processing scanning electron microscope, SEM, image data of a sample, the method comprising:
   determining a distortion function, indicative of distortion of SEM image data of a sample for each of a plurality of scan profiles;
   selecting a scan profile according to which a sample having a known design is to be scanned, based on the determined distortion functions;
   obtaining SEM image data by scanning the sample according to the selected scan profile; and
   applying the distortion function to the SEM image data to reduce distortion of the SEM image data.
24. The method of clause 23, wherein the distortion is caused by charging of the sample during a scan according to the scan profile.
25. A scanning electron microscope, SEM, for scanning a sample with electrons and detecting signal electrons emitted from the sample, the SEM comprising:
   an electron-optical device configured to direct an electron beam onto the sample according to a selected scan profile selected based on distortion functions that are indicative of distortion of SEM, image data of candidate scan profiles;
   a detector configured to detect signal electrons emitted from the sample, so as to generate SEM image data; and
   a controller configured to apply the distortion function of the selected scan profile to the SEM image data to reduce distortion of the SEM image data.
26. A non-transitory computer readable medium that stores instructions for a processor of a controller to carry out a method for processing scanning electron microscope, SEM, image data obtained by scanning a sample with electrons and detecting signal electrons emitted from the sample, the method comprising:
   determining a distortion function, indicative of distortion of SEM image data of a sample for each of a plurality of scan profiles;
   selecting a scan profile according to which a sample having a known design is to be scanned, based on the determined distortion functions;
   controlling obtaining of SEM image data by scanning the sample according to the selected scan profile; and
   applying the distortion function to the SEM image data to reduce distortion of the SEM image data.

A non-transitory computer readable medium may be provided that stores instructions for a processor of a controller (e.g., the controller 109 of FIG. 1) to carry out image assessment (e.g. metrology or inspection), image acquisition, activating charged-particle source, adjusting electrical excitation of stigmators, adjusting landing energy of electrons, adjusting objective lens excitation, adjusting secondary electron detector position and orientation, stage motion control, beam separator excitation, applying scan deflection voltages to beam deflectors, receiving and processing data associated with signal information from electron detectors, configuring an electrostatic element, detecting signal electrons, adjusting the control electrode potential, adjusting the voltages applied to the electron source, extractor electrode, and the sample, etc. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A method for correcting scan data generated by scanning a sample with charged particles and detecting signal charged particles emitted from the sample, the method comprising:
selecting at least one scan profile for scanning the sample based on at least one known distortion function, indicative of distortion of scan data, associated with the at least one selected scan profile; and
correcting scan data generated by the scanning of the sample, based on the at least one known distortion function associated with the at least one selected scan profile.

2. The method of claim 1, wherein the scan data generated by the scanning of the sample comprises distortion associated with the at least one selected scan profile and structural information associated with the sample, wherein the correcting is for compensating for the distortion associated with the at least one selected scan profile.

3. The method of claim 2, wherein the at least one selected scan profile is selected based on how separable the distortions associated with candidate scan profiles are from predicted structural information of the scan data.

4. The method of claim 2, wherein the at least one selected scan profile is selected based on how orthogonal the distortions associated with candidate scan profiles are relative to predicted structural information of the scan data.

5. The method of claim 1, wherein a plurality of selected scan profiles are selected based on how orthogonal the distortions associated with candidate scan profiles are relative to each other.

6. The method of claim 5, wherein the plurality of selected scan profiles are selected based on how orthogonal the distortions associated with candidate scan profiles are relative to each other for the sample.

7. The method of claim 1, further comprising generating a database of candidate scan profiles associated with distortion functions indicative of expected distortions caused by the respective candidate scan profiles.

8. The method of claim 7, wherein the database is generated by using physical models to predict the expected distortions.

9. The method of claim 7, wherein the database is generated by using empirical training to predict the expected distortions.

10. The method of claim 1, comprising scanning the sample using the at least one selected scan profile.

11. The method of claim 1, wherein the at least one selected scan profile determines a scan route that a charged particle beam follows over the sample.

12. A charged particle-optical apparatus configured to scan a sample with charged particles and detect signal charged particles emitted from the sample, the charged particle-optical apparatus comprising:
a charged particle-optical device configured to direct a charged particle beam onto the sample, according to a selected at least one scan profile selected based on at least one known distortion function that is indicative of distortion of scan data and is associated with the at least one selected scan profile,
a detector configured to detect signal charged particles emitted from the sample, so as to generate scan data; and
a controller configured to correct the scan data, based on the at least one known distortion function associated with the at least one selected scan profile.

13. The charged particle-optical apparatus of claim 12, wherein the scan data generated by the scanning of the sample comprises distortion associated with the at least one selected scan profile and structural information associated with the sample, wherein the controller is configured to correct the scan data to compensate for the distortion associated with the at least one selected scan profile.

14. The charged particle-optical apparatus of claim 13, wherein the controller is configured to select the at least one selected scan profile based on how separable the distortions associated with candidate scan profiles are from predicted structural information of the scan data.

15. The charged particle-optical apparatus of claim 13, wherein the controller is configured to select the at least one selected scan profile based on how orthogonal the distortions associated with candidate scan profiles are relative to predicted structural information of the scan data.

16. The charged particle-optical apparatus of claim 12, wherein the controller is configured to select a plurality of selected scan profiles based on how orthogonal the distortions associated with candidate scan profiles are relative to each other.

17. The charged particle-optical apparatus of claim 16, wherein the controller is configured to select the plurality of selected scan profiles based on how orthogonal the distortions associated with candidate scan profiles are relative to each other for the sample.

18. The charged particle-optical apparatus of claim 12, wherein the controller is configured to generate a database of candidate scan profiles associated with distortion functions indicating expected distortions caused by the respective candidate scan profiles.

19. The charged particle-optical apparatus of claim 18, wherein the controller is configured to generate the database by using physical models to predict the expected distortions.

20. The charged particle-optical apparatus of claim 18, wherein the controller is configured to generate the database by using empirical training to predict the expected distortions.
